(19) United States
(12) Patent Application Publication
(10) Pub. No.: US 2016/0281231 A1
(43) Pub. Date: Sep. 29, 2016

(54) SOURCE SUPPLY APPARATUS, SOURCE SUPPLY METHOD AND STORAGE MEDIUM

(71) Applicant: TOKYO ELECTRON LIMITED, Tokyo (JP)

(72) Inventors: Masayuki MOROI, Nirasaki City (JP); Koji MAEKAWA, Nirasaki City (JP)

(21) Appl. No.: 15/079,435

(22) Filed: Mar. 24, 2016

(30) Foreign Application Priority Data
Mar. 27, 2015 (JP) 2015-066938
Dec. 3, 2015 (JP) 2015-236549

(51) Int. Cl. C23C 16/455; C23C 16/52

(52) U.S. Cl. CPC C23C 16/45525; C23C 16/52

(57) ABSTRACT

A source supply apparatus configured to supply a source material sublimated from a solid source material together with a carrier gas to a source consumption zone, includes a source material supplier defining a sealed space and resolidifying and precipitating the source material in a thin film form of, a carrier gas supply passage through which the carrier gas is supplied to the source material supplier, a temperature adjustment part configured to adjust temperature of the source material supplier, a supply passage through which the source material and the carrier gas are supplied from the source material supplier to the source consumption zone, a flow rate measurement part measuring a flow rate of the source material supplied from the source material supplier to the source consumption zone, and a controller configured to control the temperature adjustment part based on a measured flow rate obtained from the flow rate measurement part.

### CROSS-REFERENCE TO RELATED APPLICATIONS

This application claims the benefit of Japanese Patent Application Nos. 2015-066938 and 2015-236549, filed on Mar. 27, 2015 and Dec. 3, 2015, respectively, in the Japan Patent Office, the disclosures of which are incorporated herein in their entirety by reference.

### TECHNICAL FIELD

The present disclosure relates to a technology for supplying a source material to a source consumption zone through sublimation of a solid source material.

### BACKGROUND

As a semiconductor manufacturing process, a film forming process includes so-called atomic layer deposition (ALD), in which a source gas and a reaction gas used in, for example, oxidation, nitridation or reduction of the source gas are alternately supplied, chemical vapor deposition (CVD) in which a source gas is decomposed or reacts with the reaction gas in a vapor phase, and the like. As a source gas used in such a film forming process, a gas obtained through sublimation of a solid source material is often used in order to reduce, as much as possible, the amount of impurities introduced into a substrate while improving density of crystals after the film forming process, and is used, for example, in formation of a high dielectric layer.

A source supply apparatus using a solid source material has been known, in which, for example, an inert gas, for example, nitrogen gas, is supplied as a carrier gas into a source container surrounded by a heater, and a sublimated gas is supplied together with the carrier gas into a process chamber through a gas supply passage. As such, a source gas is a mixture of a carrier gas and a source material in a gaseous state, and, for the control of thickness or quality of a film formed on a wafer, accurate adjustment of the amount of the source material (flow rate of the source material included in the source gas) is required.

However, an amount of the source material vaporized in the source container varies depending upon a filling amount of the source material, and when the source material is a solid, the sublimated amount of the source material can vary due to a biased location of the source material within the source container or can vary depending on a grain size of the solid source material. If the source material is a solid, sublimation of the source material requires heat, thereby decreasing temperature in the source container. However, since no convection occurs within the source container of the solid source material, a biased temperature distribution can be generated within the source container. As a result, the sublimated amount of the source material easily becomes unstable.

Moreover, there is disclosed a technology in which, for example, when the supply amount of the source gas becomes smaller, the flow rate of the source gas is increased by increasing the flow rate of a carrier gas so as to stabilize the flow rate of the source material. However, when the flow rate of the carrier gas is increased, the flow rate of the source material is increased and the flow rate of the carrier gas is also increased. Thus, the concentration of the source material is lowered, so that there is a concern that designed film quality cannot be obtained.

Moreover, a method of controlling a heating temperature of the solid source material in order to adjust the supply of the source material is difficult to be employed, since it takes a long time for heat to be transferred from a heater to the solid source material through the source container, thereby providing a problem of late response.

### SUMMARY

Some embodiments of the present disclosure provide a technology for supplying a source material to a source consumption zone through sublimation of a solid source material.

According to the embodiments of the present disclosure, there is provided a source supply apparatus configured to supply a source material sublimated from a solid source material together with a carrier gas to a source consumption zone, including: a source material supply source defining a sealed space and configured to resolidify and precipitate the source material sublimated from the solid source material in a form of a thin film therein; a carrier gas supply passage through which the carrier gas is supplied to the source material supply source; a temperature adjustment part configured to adjust temperature of the source material supply source; a supply passage through which the source material sublimated from the solid source material and the carrier gas are supplied from the source material supply source to the source consumption zone; a flow rate measurement part configured to measure a flow rate of the source material supplied from the source material supply source to the source consumption zone; and a controller configured to control the temperature adjustment part based on a measured flow rate value obtained from the flow rate measurement part.

According to the embodiments of the present disclosure, there is provided a source supply method for supplying a carrier gas together with a source material sublimated from a solid source material to a source consumption zone, including: sublimating the solid source material precipitated in a source material supply source by heating the source material supply source which defines a sealed space and which resolidifies and precipitates the source material sublimated from the solid source material in a form of a thin film therein; supplying the carrier gas and a sublimated source material from the source material supply source to the source consumption zone though a supply passage by providing the carrier gas into the source material supply source; measuring a flow rate of the source material supplied from the source material supply source to the source consumption zone; and controlling a temperature of the source material supply source based on the measured flow rate value of the source material measured in the measuring the flow rate of the source material.

According to the embodiments of the present disclosure, there is provided a non-transitory computer-readable storage medium storing a computer program used in a source supply apparatus for supplying a carrier gas together with a source material sublimated from a solid source material to a source consumption zone, wherein the computer program comprises a step group for implementing the source supply method described above.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an overall configuration view of a film forming apparatus to which a source supply apparatus according to an embodiment of the present disclosure is applied.

FIG. 2 is a configuration view of a source supply system installed to the source supply apparatus.

FIG. 3 is a perspective view of first and second source material capturing portions.

FIG. 4 is a plan view of the first and second source material capturing portions.

FIG. 5 is a configuration view of a controller provided in the source supply apparatus.

FIG. 6 is a diagram illustrating an operation of the source supply apparatus according to the embodiment of the present disclosure.

FIG. 7 is a diagram illustrating an operation of the source supply apparatus according to the embodiment of the present disclosure.

FIG. 8 is a diagram illustrating an operation of the source supply apparatus according to the embodiment of the present disclosure.

FIG. 9 is a configuration view illustrating another example of a temperature regulator.

FIG. 10 is a configuration view of a source supply system installed in a source supply apparatus according to another embodiment of the present disclosure.

FIG. 11 is a configuration view illustrating a portion of the source supply apparatus according to another embodiment of the present disclosure, together with a controller.

FIG. 12 is a flowchart illustrating an operation of a further embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

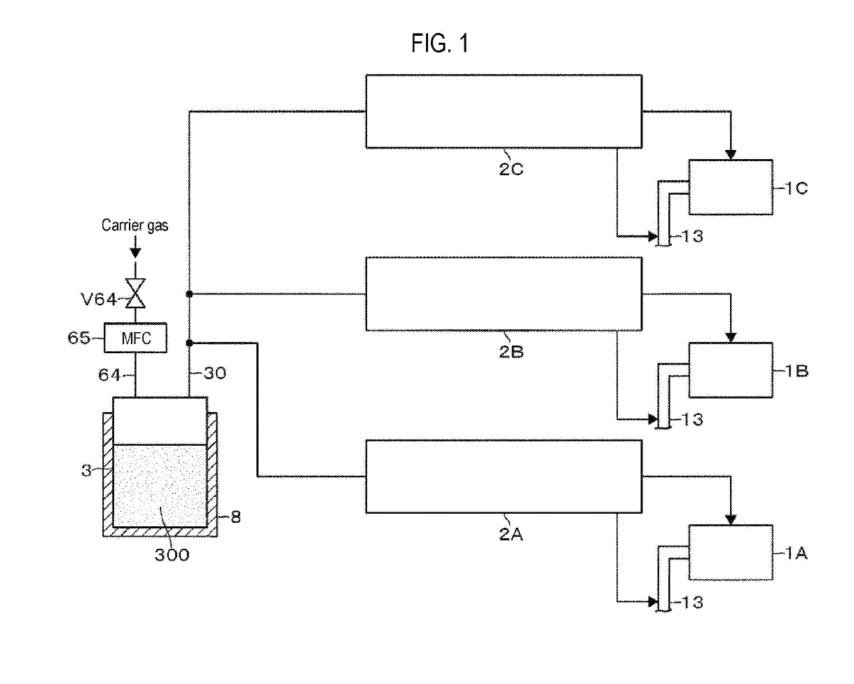

Embodiments of a source gas supply apparatus according to the present disclosure applied to a film forming apparatus will be described with reference to FIGS. 1 to 5. As shown in FIG. 1, the film forming apparatus includes: a plurality of, for example, three, film forming processing sections 1A to 1C corresponding to consumption zones of a source gas for performing film forming process on a substrate, that is, a semiconductor wafer (hereinafter, “wafer”), through chemical vapor deposition (CVD); source supply systems 2A to 2C supplying a source gas to the film forming processing sections 1A to 1C, respectively; and a main source container 3 commonly supplying a source material to each of the source supply systems 2A to 2C, as described below. In this example, a case in which a tungsten (W) film is formed using a source gas including WCl₆ (tungsten hexachloride) as a source material and hydrogen (H₂) which is a reaction gas (reduction gas), as a process gas, through CVD will be described.

The main source container 3 is formed of, for example, stainless steel, and accommodates WCl₆ (tungsten hexachloride) in a solid (powder) state at room temperature as a solid source material 300. The ceiling of the main source container 3 is connected to a downstream end of a carrier gas supply passage 64 through which an inert gas, for example, nitrogen (N₂) gas, acting as a carrier gas is supplied to the main source container 3, and to an upstream end of a source supplementing pipe 30 by supplying a source gas from the main source container 3 to each of the source supply systems 2A to 2C. The carrier gas supply passage 64 is provided with a mass flow controller (MFC) 65 for controlling the flow rate of the carrier gas and a valve V64.

The main source container 3 is covered by a heater 8, for example, a jacket-shaped mantle heater having a resistance heating element. The heater 8 of the main source container 3 is configured to regulate the temperature of the main source container 3 by adjusting power supplied from a power supply (not shown). A set temperature of the heater 8 of the main source container 3 is set to a temperature within a range in which the solid source material 300 is sublimated, and in which WC₁₆ is not decomposed, for example, to a temperature of 150 degrees C.

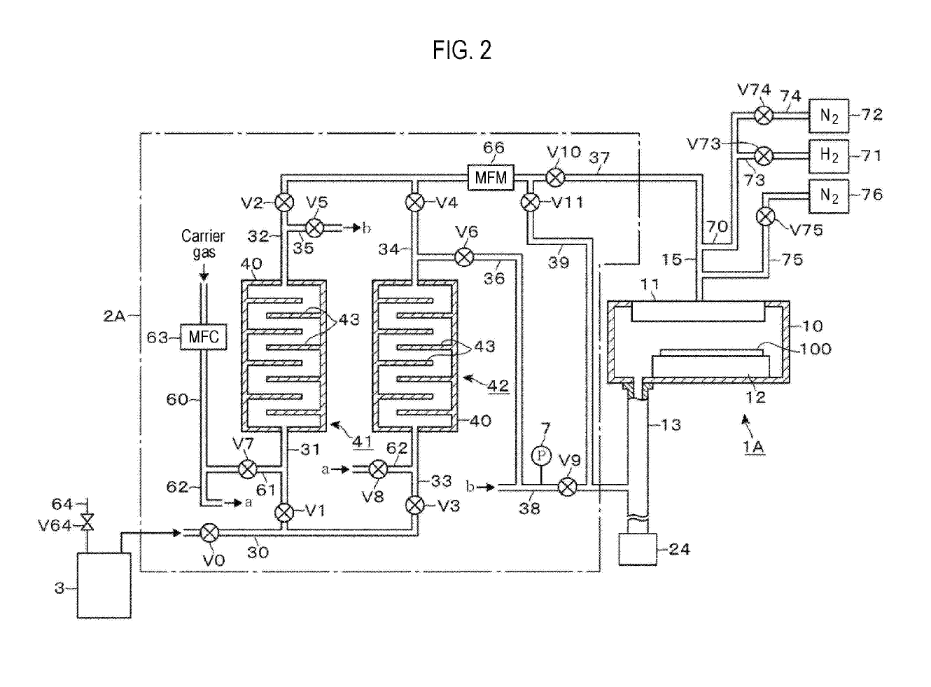

Next, the film forming processing sections 1A to 1C and the source supply systems 2A to 2C will be described, through a film forming processing section 1A and a source supply system 2A connected to the film forming processing section 1A as an example. As shown in FIG. 2, the film forming processing section 1A is provided with a loading plate 12, disposed within the vacuum container 10, which maintain a wafer 100 in a horizontal state and includes a heater (not shown), and a gas introducing portion 11 (specifically, a gas shower head) through which a source gas and the like are introduced into the vacuum container 10. The vacuum container 10 is vacuum-exhausted by a vacuum evacuator 24 connected to a vacuum pump through an exhaust pipe 13. In the vacuum container 10, a film forming process is performed on a surface of the heated wafer 100 when the source gas is introduced into the vacuum container.

A gas supply pipe 15 is connected to the gas introducing portion 11 and is also connected to a source gas supply pipe 37 constituting a source supply passage through which a source gas including WCl₆ is supplied from the source supply system 2A, a reaction gas supply pipe 70 configured to supply a reaction gas reacting with the source gas, and a substitution gas supply pipe 75 configured to supply a substitution gas. The reaction gas supply pipe 70 is bifurcated at the other end thereof into a gas supply pipe 73 connected to a reaction gas supply source 71 and a gas supply pipe 74 connected to an inert gas supply source 72, for example, a nitrogen (N₂) gas supply source. Further, the substitution gas supply pipe 75 is connected at the other end thereof to a substitution gas supply source 76, for example, a nitrogen (N₂) gas supply source. In the drawings, reference numerals V73 to V75 indicate valves provided in the gas supply pipe 73, the gas supply pipe 74 and the substitution gas supply pipe 75, respectively. In addition, the source gas supply pipe 37 is provided with a mass flow controller (MFC) 66 for measuring the flow rate of a source gas flowing through the source gas supply pipe 37, and a valve V10 arranged in this order from an upstream side. Further, an exhaust pipe 39 is connected to a downstream side of the mass flow meter 66 and to an upstream side of the valve V10 such that the source gas is discharged therethrough to exhaust the container using the vacuum evacuator 24. In the drawings, reference numeral V11 indicates a valve.

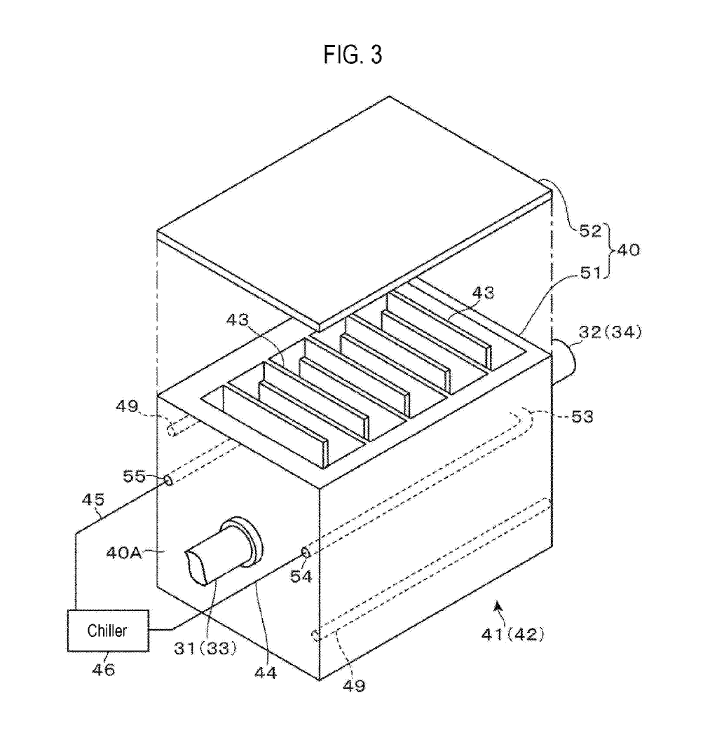

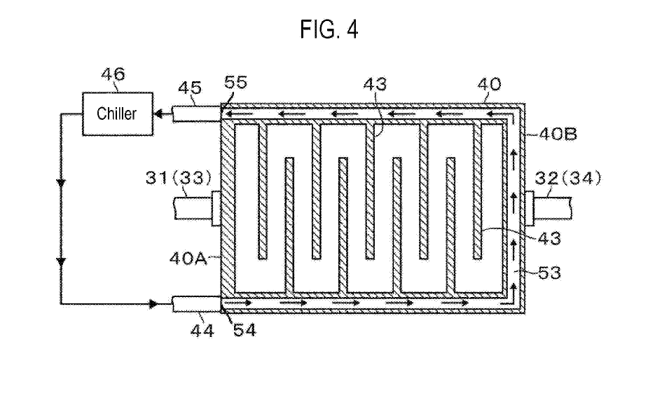

The source supply system 2A is provided with a first source material capturing portion 41 and a second source material capturing portion 42 which resolidify and capture the source material being supplied together with the carrier gas after being sublimated in the main source container 3, and which act as source material suppliers with respect to the film forming processing section 1A. As shown in FIGS. 3 and 4, each of the first and second source material capturing portions 41, 42 includes a case body 40 having a rectangular barrel shape and composed of a lower case 51 which is formed of, for example, stainless steel and has a substantially box shape open at an upper side thereof and a size of 130 mm×130 mm×175 mm (height×width×length), and a cover 52, which is formed of stainless steel and welded to an upper surface of the lower case 51 to close the open side of the lower case 51. Hereinafter, one side of the case body 40 in the longitudinal direction thereof will be referred to a front side 40A and the other side thereof will be referred to as a rear side 40B.

Plate-shaped capturing plates 43 having a solidification surface are formed on an inner surface of the case body 40. A plurality of capturing plates 43 extending from a right sidewall of the lower case 51 towards a left sidewall, when viewed from the front side of the lower case 51, and a plurality of capturing plates 43 extending from the left sidewall of the lower case 51 towards the right sidewall are alternately arranged in the longitudinal direction. Accordingly, a bent labyrinth type flow passage is formed in the case body 40. Alternatively, the capturing plates 43 may be formed such that they are arranged in an up-down direction of the case body 40 rather than in the left-right direction as described above. Alternatively, the capturing plates 43 may be formed by combining an alternate arrangement of the capturing plates 43 in the left-right direction and an alternate arrangement of the capturing plates 43 in the up-down direction. For example, the capturing plates 43 may be formed such that the first capturing plate 43 extends from a right side of the lower case 51, the next capturing plate 43 extends from an upper side, the next capturing plate 43 extends from a left side, and the next capturing plate 43 extends from a lower side.

The case body 40 is provided with a coolant passage 53 which is formed above the middle of the case body in the vertical direction. The coolant passage 53 extends backwards from a portion of the case body 40 near a right edge of the front side 40A of the case body 40 to the backside of the case body 40 through a right sidewall of the case body 40, and further extends along the rear side (backside) of the case body 40 and a left sidewall to a portion of the case body 40 near a left edge of the front side 40A of the case body 40. In FIG. 3, reference numeral 54 indicates an inlet of the coolant passage 53 to which a supply pipe 44 for supplying a coolant from a chiller 46 is connected, and reference numeral 55 indicates an outlet of the coolant passage 53 to which a discharge pipe 45 for discharging the coolant to the chiller 46 is connected. In this way, a coolant, for example, cooling water, circulates in the case body 40 through the coolant passage 53 extending around the interior of the case body 40. As the cooling water circulates in the case body 40, the first and second source material capturing portions 41, 42 can be forcibly cooled to a temperature less than or equal to the coagulating point of WCl₆ which is a main component of the source gas, at which impurities contained in the WCl₆ such as WCl₂O₂ (tungsten dichloride dioxide) or WCl₄O (tungsten tetrachloride oxide) is not coagulated. The coolant passage 53, the supply pipe 44, the discharge pipe 45 and the chiller 46 constitute a cooling part.

Furthermore, for example, resistance heating elements constituting a heating part 49 are embedded both at an upper portion of the left sidewall of the case body 40 and at a lower portion of the right sidewall thereof and extend in the front-rear direction of the case body 40. The cooling part and the heating part 49 constitute a temperature adjustment part, and in this embodiment, the temperature adjustment part regulates the temperature of the first and second source material capturing portions 41, 42 by changing output of the heating part 49 while circulating the cooling water. The temperature adjustment part regulates the temperature of the first and second source material capturing portions 41, 42 to a temperature at which a solid source material (gas), for example, WCl₆, supplied from the main source container 3 is precipitated in the case body 40, and to a temperature at which the solid source material precipitated in the case body 40 is sublimated in order to supply a gas of the solid source material to the film forming processing section 1A.

Referring to FIGS. 2 to 4, a downstream end of one branch pipe 31 among branch pipes 31, 33 branching out from the source supplementing pipe 30 is connected to the center of the front side 40A of the case body 40 in the first source material capturing portion 41, and a downstream end of the other branch pipe 33 is connected to the center of the front side 40A of the case body 40 in the second source material capturing portion 42. The source supplementing pipe 30 and the branch pipes 31, 33 correspond to a source supplementing passage. Furthermore, reference numeral V0 indicates a valve.

Furthermore, an upstream end of one branch pipe 32 among branch pipes 32, 34 branching out from the source gas supply pipe 37 is connected to the center of the rear side 40B of the case body 40 in the first source material capturing portion 41, and an upstream end of the other branch pipe 34 is connected to the case body 40 in the second source material capturing portion 42. The source gas supply pipe 37 and the branch pipes 32, 34 correspond to a source supply passage. Accordingly, the first source material capturing portion 41 and the second source material capturing portion 42 are connected in parallel to the passages between the main source container 3 and the film forming processing section 1A. Valves V1 and V2 are provided in the branch pipes 31, 33 at upstream sides of the first and second source material capturing portions 41, 42, respectively, and valves V2 and V4 are provided to the branch pipes 32, 34 at downstream sides of the first and second source material capturing portions 41, 42, respectively.

Further, the source supply system 2A is provided with a carrier gas supply pipe 60, which supplies an inert gat as a carrier gas, for example, N₂ gas heated to about 150 degrees C., to the first and second source material capturing portions 41, 42 in order to supply the source gas from the first and second source material capturing portions 41, 42 to the film forming processing section 1A. The carrier gas supply pipe 60 is bifurcated into pipes 61, 62. Here, the pipe 61 is connected to a downstream side of the valve V1 in the branch pipe 31 and the pipe 62 is connected to a downstream side of the valve V3 in the branch pipe 33. Further, the carrier gas supply pipe 60 is provided with a mass flow controller to control the flow rate of the carrier gas. Reference numerals V7 and V8 indicate valves.

Further, the source supply system 2A is provided with a joint pipe 38 through which a gas passing through the first and second source material capturing portions 41, 42 during cooling of the first and second source material capturing portions 41, 42 is discharged. The joint pipe 38 is divided into exhaust pipes 35, 36. The exhaust pipe 35 is connected to an upstream side of the valve V2 in the branch pipe 32 and the exhaust pipe 36 is connected to an upstream side of the valve V4 in the branch pipe 34. The exhaust pipes 35, 36 and the joint pipe 38 are provided with valves V5, V6, V9, respectively. Furthermore, the joint pipe 38 is provided with a pressure gauge 7 which measures internal pressure of the first and second source material capturing portions 41, 42 or pressure of the gas exhausted from the first and second source material capturing portions 41, 42.

Furthermore, the source supplementing pipe 30, the branch pipes 31, 33, the source gas supply pipe 37, the branch pipes 32, 34, the exhaust pipes 35, 36 and the joint pipe 38 through which a gas containing the source gas passes are covered with, for example, a tape heater (not shown) and the like, and regions of these pipes covered with the tape heater are heated to a temperature at which the source gas is not precipitated, for example, 160 degrees C.

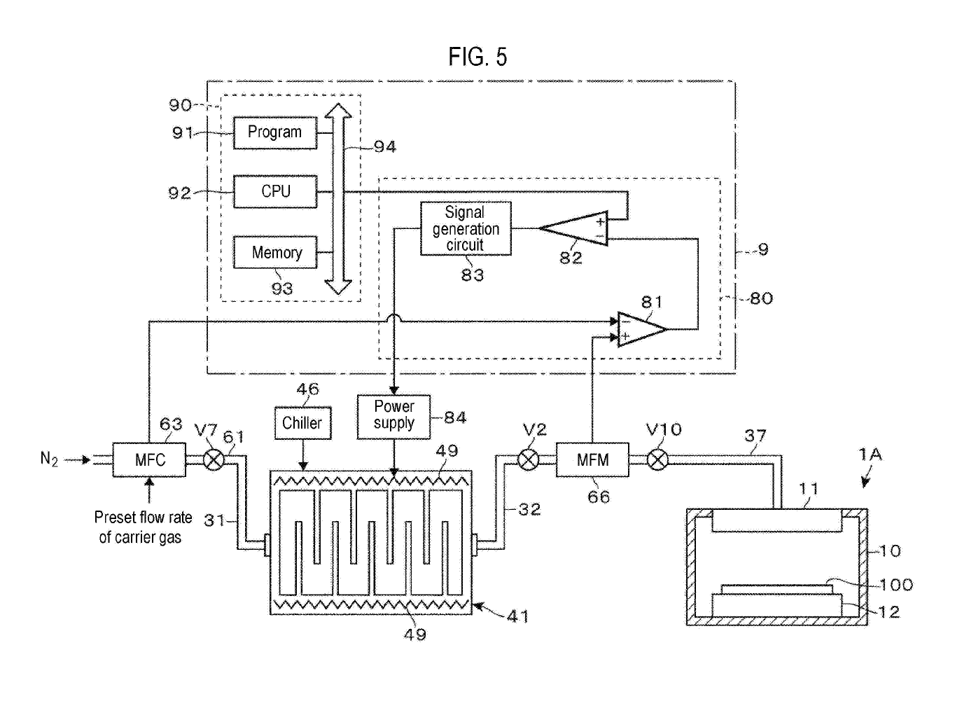

Next, the controller 9 of the film forming apparatus will be described with reference to FIG. 5. Referring to FIG. 5, the controller 9 includes a circuit unit 80 configured to control heat discharge rate of the heating part 49, and a computer 90. The circuit unit 80 is provided with, for example, a first PID (proportional, integral, differential) operator 81 configured to obtain a value (difference value) of difference between a flow rate value obtained from the mass flow meter 66 and a flow rate value obtained from a mass flow controller 63. A second PID operator 82 which obtains a difference value between the difference value obtained by the first PID operator 81 and a preset value is provided in a rear end of the first PID operator 81. In FIG. 5, a reference numeral 84 indicates a power supply for supplying power to the heating part 49, which includes, for example, a switching element for performing phase control.

The second PID operator 82 is provided at a rear end thereof with a signal generation circuit 83 which generates a timing signal for turning on/off the switching element of the power supply 84, for example, a control signal for controlling a firing angle of a semiconductor switching element, based on the difference value obtained by the second PID operator 82.

The difference value between the measured flow rate value obtained from the mass flow meter 66 and the measured flow rate value obtained from the mass flow controller 63 corresponds to a flow rate of the source material sublimated in the first source material capturing portion 41 when the first source material capturing portion 41 is used as a source material supply source. The preset value input to the second PID operator 82 corresponds to a preset value of the flow rate of the source material, and thus, when the flow rate of the source material is maintained at the preset value, power supplied from the power supply 84 to the heating part 49 does not change since an integrated value, until that time, is output from the second PID operator 82 as an output.

On the other hand, when the flow rate of the source material is decreased below the preset value, the output value from the second PID operator 82 increases and the timing signal output from the signal generation circuit 83 is changed such that the on-time of the switching element becomes long, thereby increasing power supplied to the heating part 49. Furthermore, when the flow rate of the source material exceeds the preset value, the output value from the second PID operator 82 decreases and the timing signal output from the signal generation circuit 83 is changed such that the on-time of the switching element is shortened, thereby decreasing power supplied to the heating part 49.

The computer 90 includes a program storage 91, a central processing unit (CPU) 92, and a memory 93. A reference numeral 94 indicates a bus. A program stored in the program storage 91 is composed of a step group for implementing operation of the film forming apparatus. The term “program” is used herein as including software such as a process recipe and the like. The preset value of the flow rate of the source material input to the second PID operator 82 is read from, for example, a process recipe stored in the program storage 91. The program is stored in a storage medium, for example, a hard disk, a compact disk, a magnet optical disk, a memory card, and the like, and is installed therefrom onto a computer.

A method of controlling power supplied from a power supply 84 to the heating part 49 based on the difference value between the measured flow rate value obtained from the mass flow meter 66 and the measured flow rate value obtained from the mass flow controller 63 may be realized using software instead of using hardware, for example, using the PID operation. In this case, a method can be used, in which the difference value (difference value between the flow rate value of the source material and the preset value) between the preset value and the difference value between the measured flow rate value obtained from the mass flow meter 66 and the measured flow rate value obtained from the mass flow controller 63 is obtained, and in which a table including the difference value and a command value for the power supply 84 corresponding to the difference value is read from the memory.

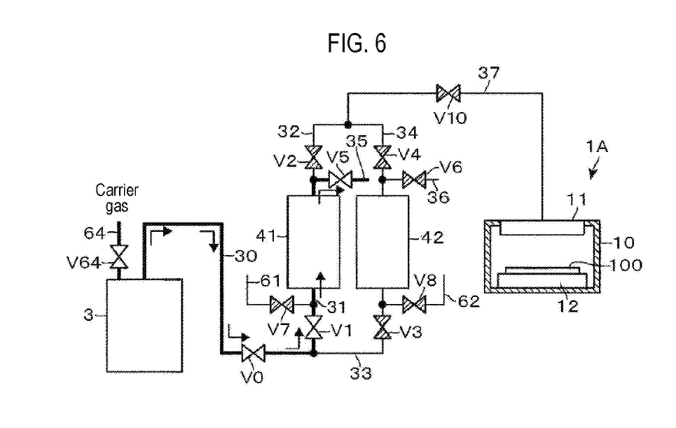

Next, an operation of the source supply apparatus according to the aforementioned embodiment will be described. First, the film forming apparatus including the source supply apparatus according to the present disclosure will be described using the source supply system 2A with reference to FIGS. 6 to 8. The operation of the apparatus for performing the film forming process is started. First, the heater 8 of the main source container 3 is turned on to heat the main source container 3 to a temperature of, for example, 150 degrees C., so that a solid source material 300 is sublimated and the concentration of the source material within the main source container 3 is increased to concentration near the saturation concentration. Further, the heating part 49 is turned on to heat the first source material capturing portion 41 to a temperature of, for example, 60 degrees C. Further, in an initial operation during the startup of the apparatus, the source material may be captured by both the first source material capturing portion 41 and the second source material capturing portion 42. However, the following description will be given of a case where the source material is only captured by the first source material capturing portion 41.

Then, as shown in FIG. 6, the valves V0, V1, V5, V9 are opened together with the valve V64 to supply a carrier gas to the main source container 3. Accordingly, sublimation of the solid source material 300 is promoted to saturate the source material within the main source container 3, and the saturated source material is supplied together with a carrier gas to the case body 40 of the first source material capturing portion 41 through the source supplementing pipe 30 and the branch pipe 31. The gas having passed through the case body 40 is discharged from the branch pipe 32, passes through the exhaust pipe 35, and then is exhausted through the exhaust pipe 13 shown in FIG. 2.

An inner temperature of the case body 40 of the first source material capturing portion 41 is set to 60 degrees C., which is lower than the coagulating point of WCl₆ used as the source material. Accordingly, while the source material in the gaseous state passes through a bent labyrinth-shaped passage formed by the plurality of capturing plates 43, the source material is captured and precipitated (resolidified) by the capturing plates 43 and the inner surface of the case body 40, so that WCl₆ is adhered in the form of a thin film to the inner surface of the capturing plate 43. The first source material capturing portion 41 has a size of the case body 40 thereof, the distance between the capturing plates 43, the number of capturing plates 43, and the like, which are determined such that the source material in the source gas can be substantially completely resolidified when the carrier gas and the source gas containing the source material pass through the first source material capturing portion 41.

Here, a commercially available solid source material of WCl₆ typically includes WCl₆ and a very small amount of WCl₂O₂ or WCl₄O. Since WCl₆ has a coagulating point higher than 60 degrees C., WCl₆ can be solidified again when being cooled to 60 degrees C., whereas, since WCl₂O₂ or WCl₄O has a coagulating point lower than 60 degrees C., WCl₂O₂ or WCl₄O is not coagulated at 60 degrees C. Accordingly, when the temperature of the first source material capturing portion 41 is set to 60 degrees C. and the source gas is caused to pass through the first source material capturing portion 41 and is resolidified, WCl₆ is precipitated in the first source material capturing portion 41 while WCl₂O₂ or WCl₄O is exhausted together with the carrier gas after passing through the first source material capturing portion 41.

When the amount of the source material precipitated in the first source material capturing portion 41 exceeds a preset amount, for example, 10 g to 800 g, the valves V0, V1, V64 are closed. A time point at which the amount of the source material precipitated in the first source material capturing portion 41 reaches the preset amount is controlled by, for example, a period of time for which the gas passes through in the first source material capturing portion 41. In this way, the first source material capturing portion 41 is prepared to act as a source material supply source with respect to the film forming processing section 1A. Then, a wafer 100 is loaded on the loading plate 12 in the film forming processing section 1A and is heated while the vacuum container 10 is vacuum-evacuated. Thereafter, film forming is performed by, for example, CVD, and the supply of the source gas is performed as follows.

First, before start of film forming, the heating part 49 of the first source material capturing portion 41 is turned on to increase the inner temperature of the case body 40 to a preset temperature ranging from 150 degrees C. to 200 degrees C., for example, to 150 degrees C., so that the source material precipitated in the first source material capturing portion 41 is sublimated. In this case, the supply of power to the heating part 49 is performed by providing an initial value of the firing angle of the switching element of the power supply 84 from the controller 9. Then, a signal selector (not shown) interposed between the second PID operator 82 and the signal generation circuit 83 is switched to a circuit for supplying the initial value. Then, the valves V2, V7, and V11 are opened to supply a carrier gas to the first source material capturing portion 41, and the source gas is exhausted by the vacuum evacuator 24 from the first source material capturing portion 41, bypassing the film forming processing section 1A.

In other words, this pre-operation is performed in order to stabilize the concentration of the source material in the source gas before a series of supply processes. Namely, during this operation, an output value of the second PID operator 82 is input to the signal generation circuit 83 by the signal selector (not shown) interposed between the second PID operator 82 and the signal generation circuit 83 to effectuate the PID control. Thus, heat discharge rate of the heating part 49 is controlled such that the flow rate of the source material becomes a preset value based on the difference value between the measured flow rate value of the gas obtained from the mass flow meter 66 and the measured flow rate value of the gas obtained from the mass flow controller 63. Further, the gas is exhausted from the first source material capturing portion 41 for a predetermined period of time, and the valves V5, V11 are closed while the valves V2, V10 are opened, so that the source gas is supplied to the vacuum container 10 while a reaction gas (H₂ gas) together with a dilution gas (N₂ gas) are supplied to the vacuum container 10 by opening the valves V73 and V74. As a result, the source material, that is, WCl₆, is reduced by H₂, so that a W layer having a predetermined thickness is formed on the surface of the wafer 100. After film forming is performed for a predetermined period of time, the valves V2, V7, V10 are closed to stop supply of the source gas to the vacuum container 10 while closing the valves V73, V74 to stop supply of the reaction gas to the vacuum container 10. Furthermore, the valve V75 is opened to supply a substitution gas (N₂ gas) to the vacuum container 10, thereby substituting an atmosphere of the vacuum container 10. Thereafter, the wafer 100 is withdrawn from the vacuum container 10.

Description will be given on control of the flow rate of the source material in film forming process by raising a case of supplying the source material from the first source material capturing portion 41 as an example.

Since, as described above, power is supplied to the heating part 49 such that the flow rate of the source material becomes the preset value, the flow rate of the source material is maintained at the preset value, even after the valve V11 is closed while the valves V2, V10 being opened and thus the place to which the source gas is supplied is switched from a bypass passage through the exhaust pipe 39 to the vacuum container 10.

Further, even when the source gas is supplied into the vacuum container 10, the measured flow rate value obtained from the mass flow meter 66 and the measured flow rate value obtained from the mass flow controller 63 are input to the controller 9, and thus the temperature control can be performed as described above by comparing the difference value obtained therefrom with the preset value. Accordingly, for example, when the flow rate of the source material supplied from the first source material capturing portion 41 is decreased below the preset value, power supplied to the heating part 49 is increased by the control of the controller 9 described above in detail and the temperature of the first source material capturing portion 41 is increased to return the flow rate of the source material to the preset value. In addition, when the flow rate of the source material supplied from the first source material capturing portion 41 exceeds the preset value, power supplied to the heating part 49 is decreased and the temperature of the first source material capturing portion 41 is decreased to return the flow rate of the source material to the preset value. In a relationship between a correction amount of the flow rate of the source material, that is, a correction amount (increment or decrement) of a sublimation amount of the source material, and temperature variation of the source material, for example, WCl₆ has a correction amount of −19% at −4 degrees C. and a correction amount of +24% at +4 degrees C. when the referential temperature is 170 degrees C.

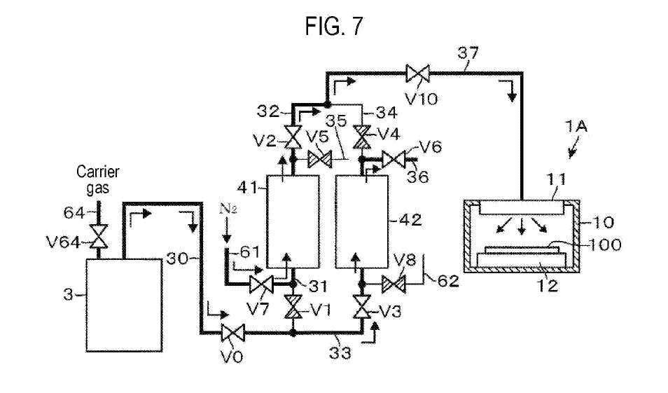

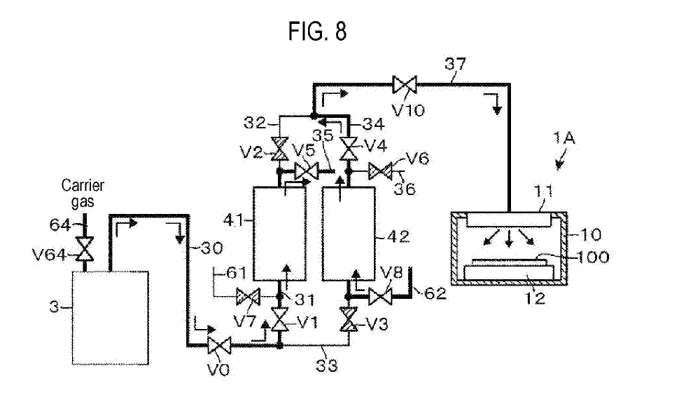

On the other hand, while the first source material capturing portion 41 is used as a source gas supply source, the valves V3, V6 are opened, as shown in FIG. 7, in order to supplement the source material into the second source material capturing portion 42. The supplementing process is performed in the same way with respect to the supplementing of the source material in the first source material capturing portion 41. Further, after a predetermined number of wafers 100 is processed using the first source material capturing portion 41 as the source gas supply source, the valves V2, V3, V6, V7 are closed and the valves V1, V5, V4, V8 are opened, as shown in FIG. 8. As a result, instead of the first source material capturing portion 41, the second source material capturing portion 42 is used as the source gas supply source to supply the source material to the film forming processing section 1A. Here, as in the first source material capturing portion 41, the temperature of the second source material capturing portion 42 is adjusted depending upon the flow rate of the source material, thereby adjusting the flow rate of the source material to a predetermined flow rate.

As an indicator of timing for converting the source gas supply source between the first source material capturing portion 41 and the second source material capturing portion 42, for example, the number of wafers 100 can be used. In this case, for example, timing before the concentration of the source gas supplied to the film forming processing section 1A becomes unstable due to decrease in the amount of the source material attached to one of the first and second source material capturing portions 41, 42 used as the source gas supply source is previously investigated.

In this way, a process of supplementing the source material from the main source container 3 to the second source material capturing portion 42 while supplying the source gas to the film forming processing section 1A using the first source material capturing portion 41 shown in FIG. 7 as the source material supply source, and a process of supplementing the source material from the main source container 3 to the first source material capturing portion 41 while supplying the source gas to the film forming processing section 1A using the second source material capturing portion 42 shown in FIG. 8 as the source material supply source are alternately repeated. That is, the first source material capturing portion 41 and the second source material capturing portion 42 are alternately used as the source material supply source. Further, in the other source supply systems 2B, 2C shown in FIG. 1, a source gas is supplied to the film forming processing sections 1B, 1C in the same way.

In the source supply apparatus according to the aforementioned embodiment, the first and second source material capturing portions 41, 42 in which the source gas obtained by sublimation of the solid source material is re-solidified and precipitated in the form of a thin film on the inner wall of the case body 40 and the surface of the capturing plate 43 are used as the source material supply source with respect to the film forming processing section 1A. In addition, the flow rate of the source material is obtained by subtracting the flow rate of the gas in the upstream side of the first and second source material capturing portions 41, 42 from the flow rate of the gas in the downstream side of the first and second source material capturing portions 41, 42, and heat discharge rate of the heating part is controlled based on the flow rate of the source material. Since the solid source material is adhered in the form of the thin film on the inner wall of the case body 40, good heat transfer from the case body 40 to the entirety of the solid source material can be achieved when heat is supplied to the case body 40, and thus the sublimation amount of the solid source material is sensitively changed through temperature adjustment by the heating part 49.

Accordingly, when the measured flow rate value of the source material deviates from the preset value, the flow rate of the source material is caused to return to the preset value by being responsively increased or decreased, thereby enabling a stable film forming process through stable supply of the source material. Furthermore, this process suffers from less variation in concentration of the source material in the source gas supplied to the film forming processing section 1A, compared with a method of controlling the flow rate of the carrier gas.

Furthermore, each of the first and second source material capturing portions 41, 42 has a structure in which the capturing plates 43 extending from the right side wall or the left side wall are alternately arranged in the front-rear direction to form a labyrinth structure, thereby securing a large capturing amount.

The present disclosure can be applied to a process in which a preset value for the supply amount of a source material is to be changed when the source material is continuously supplied with respect to a single sheet of wafer 100, for example, case of forming upper and lower layers different from each other on a surface of the wafer 100. In this case, in order to change a supply amount of the source material when forming the upper layer to a supply amount of the source material for forming the lower layer, that is, in order to change a preset value of the flow rate of the source material per se, the flow rate of the carrier gas is changed.

In processing a plurality of lots of wafers 100, a preset value of the flow rate of the source material is sometimes changed according to the lots. Even in this case, the flow rate of the carrier gas is changed.

When the preset value of the flow rate of the source material is changed, it is desirable that the flow rate of the carrier gas be changed in order to avoid significant change of heating temperature of the source material. However, if the heating temperature is not significantly changed, the flow rate of the source material may be changed by changing the heating temperature or by changing both the flow rate of the carrier gas and the heating temperature.

With regard to the measurement of the flow rate of the source material, when calibration of the mass flow meter 66 is performed using the carrier gas, it should be noted that, strictly speaking, the mass flow meter 66 shows different measurement values between the case where a mixture of the carrier gas and the sublimated source gas is used and the case where only the carrier gas flows. Accordingly, when such tolerance is taken into account for the control, an integrated value obtained through integration of a predetermined coefficient with the difference value between the measured flow rate value obtained from the mass flow meter 66 and the measured flow rate value obtained from the mass flow controller 63 may be used as the flow rate of the source material. Alternatively, a difference value between an integrated value of the measured flow rate value obtained from the mass flow meter 66 and an integrated value of the measured flow rate value obtained from the mass flow controller 63 may be treated as the flow rate of the source material. In some implementations, a light emitting section and a light receiving section may be formed at a downstream side of the first and second source material capturing portions 41, 42 such that light including an absorption wavelength area of the solid source material forms an optical axis in a direction that intersects a gas flow direction, and the flow rate of the source material is measured based on the amount of light received by the light receiving section.

Film forming process may be performed by ALD. In ALD, a W layer having a predetermined thickness is formed by repeating a cycle of supplying a source gas containing WCl₆→substitution gas (N₂ gas)→reaction gas (mixture gas of H₂ gas and carrier gas (N₂ gas))→substitution gas into the vacuum container 10. In this case, the flow rate of the source material may be stabilized to reduce variation in concentration of the source material supplied to the vacuum container 10.

The first and second source material capturing portions 41, 42 are not limited to the structure of the aforementioned embodiments, and may have a structure in which, for example, hexagonal column-shaped hollow pipes are arranged within the case body 40 in a parallel relationship with each other in the longitudinal direction of the case body 40the case body 40, forming a honeycomb shape when viewed in the longitudinal direction. With this structure, the case body 40 has a large surface area, thereby providing the same effects as the case body having the structure of the aforementioned embodiments.

In some implementations, the first and second source material capturing portions 41, 42 may be configured to have a lengthened flow passage from the upstream side thereof to the downstream side thereof. For example, 36 plates of the capturing plates 43 each having a size of 80 mm×80 mm×500 mm may be installed in the case body 40. In other implementations, the case body 40 may have a cylindrical shape.

Furthermore, control of the flow rate of the source material can be achieved by combining temperature adjustment by controlling the flow rate of the cooling water within the cooling part to temperature adjustment by the heating part 49.

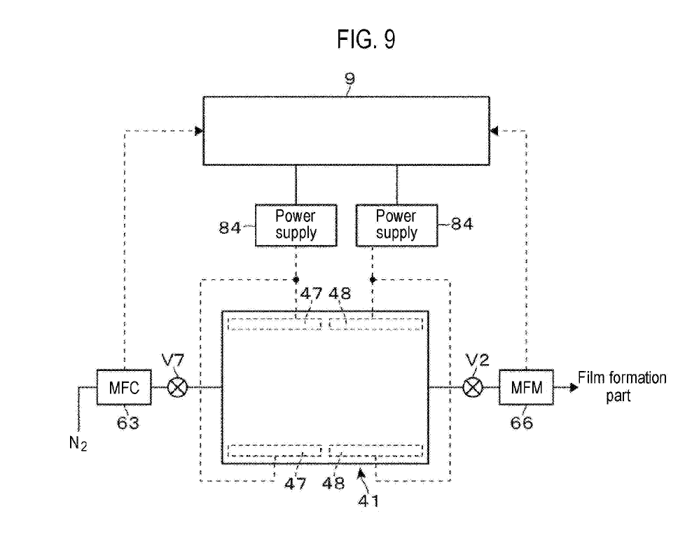

In the embodiments described above, the source material is captured by the first and second source material capturing portions 41, 42 by allowing the source gas to flow from the upstream side of the first and second source material capturing portions 41, 42 to the downstream side thereof. As a result, the source material can be more easily precipitated at the upstream side of the first and second source material capturing portions 41, 42 than the downstream side thereof, thereby providing a large precipitation amount of the source material. Accordingly, as shown in FIG. 9, a first heater 47 and a second heater 48 may be disposed in a region at the upstream side of each of the first and second source material capturing portions 41, 42 and in a region at the downstream side of each of the first and second source material capturing portions 41, 42, respectively. In this embodiment, the temperatures of the first and second heaters 47, 48 are controlled by the controller 9 such that the region at the upstream side of the first and second source material capturing portions 41, 42 is heated to a higher temperature than the region at the downstream side thereof, thereby enabling efficient sublimation of the source material precipitated in the first and second source material capturing portions 41, 42. In this implementation, when a preset temperature is, for example, 150 degrees C., the first heater 47 and the second heater 48 may be set to, e.g., 152 degrees C. and 150 degrees C., respectively, and the preset temperature of each of the first and second heaters 47, 48 may be in the range of 150 degrees C. to 200 degrees C.

In addition, although even a structure not using the source supplementing pipe 30 for supplementing the source material to the main source container 3 and the first and second source material capturing portions 41, 42 is employed, the same effects can be obtained. For example, a structure may be possible, in which the upstream side of the source material capturing portions is detachably coupled to the carrier gas supply pipe 60 while the downstream side of the source material capturing portions is detachably coupled to the source gas supply pipe 37, and in which the source material is precipitated in the form of a thin film within the source material capturing portions by, for example, an external device, and is exchanged.

Although the first and second source material capturing portions 41, 42 are used in the above embodiments, it should be understood that the first source material capturing portion 41 may be used alone.

The following description will be given of another embodiment of the present disclosure. This embodiment relates to a method of changing the flow rate of the source material. Examples of the case in which the flow rate of the source material is changed include a case in which a process recipe is changed due to a change of a lot, or a case in which a new thin film is formed on a thin film previously formed on a wafer 100 and having a different film quality from the new thin film, and the like.

For example, in order to change (increase or decrease) the flow rate of the source material supplied from the first source material capturing portion 41 to the film forming processing section 1A, a method of changing the temperature of the case body 40 of the first source material capturing portion 41 by the temperature adjustment part (see FIG. 3) obtained by combination of the heating part 49 and the coolant passage 53, or a method of changing the flow rate of the carrier gas, can be used. If the temperature is changed, for example, if the temperature is increased by 10 degrees C., there is an advantage that the flow rate of the source material can be increased about two times and can be adjusted in a wide range. However, there is also a problem that it is difficult to rapidly change the temperature of the case body 40.

On the other hand, when the flow rate of the carrier gas is changed, the flow rate of the carrier gas can be instantly changed and can be finely adjusted. Accordingly, the flow rate of the source material can be instantly changed and can also be finely adjusted. However, since the flow rate of the source material is not doubled even by, for example, doubling the flow rate of the carrier gas, the flow rate of the carrier gas should be significantly increased or decreased. Since the flow rate of the carrier gas has an upper limit value and a lower limit value required by the supply system, there may be a possibility that a desired flow rate of the source material can not be obtained by adjustment of, for example, only the flow rate of the carrier gas.

Accordingly, in this embodiment, the control of the flow rate of the source material is performed by combination of adjustment of the flow rate of the carrier gas and temperature adjustment, thereby enabling rapid control of the flow rate of the source material in a wide range of the flow rate.

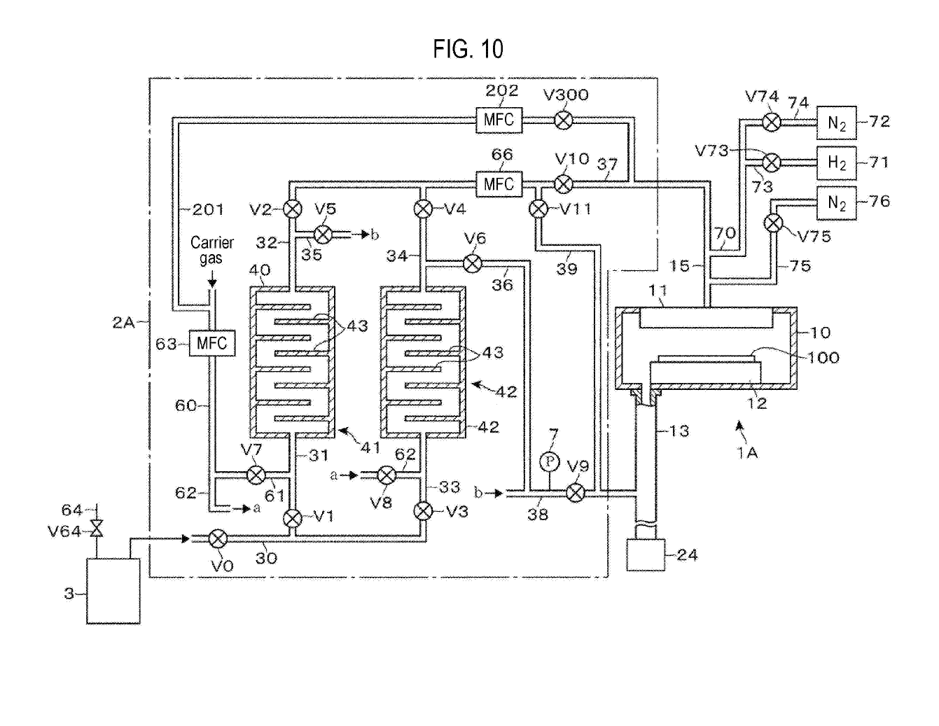

FIG. 10 shows a detailed configuration of a source supply system 2A according to another embodiment of the present disclosure. In this embodiment, a dilution gas supply pipe 201 acting as a dilution gas supply passage is branching out from the carrier gas supply pipe 60 at an upstream side of the mass flow controller 63, and a downstream end of the dilution gas supply pipe 201 is connected to a downstream side of the valve V10 in the source gas supply pipe 37 constituting the supply passage. The dilution gas supply pipe 201 is provided with a mass flow controller 202 and a valve V300 in this order from an upstream side thereof.

Since an inert gas N₂ flows through the carrier gas supply pipe 60, the dilution gas flowing through the dilution gas supply pipe 201 is N₂ gas, which is added to the mixed gas of the source gas and the carrier gas flowing through the source gas supply pipe 37. This dilution gas serves to make the concentration of the source material {flow rate of source gas/flow rate of N₂ gas (carrier gas and dilution gas)} supplied to the film forming processing section 1A constant by adjusting the flow rate of the dilution gas, when each of the flow rates of the carrier gas and the source gas is changed. Accordingly, the dilution gas flowing through the dilution gas supply pipe 201 may also be referred to as “offset gas”.

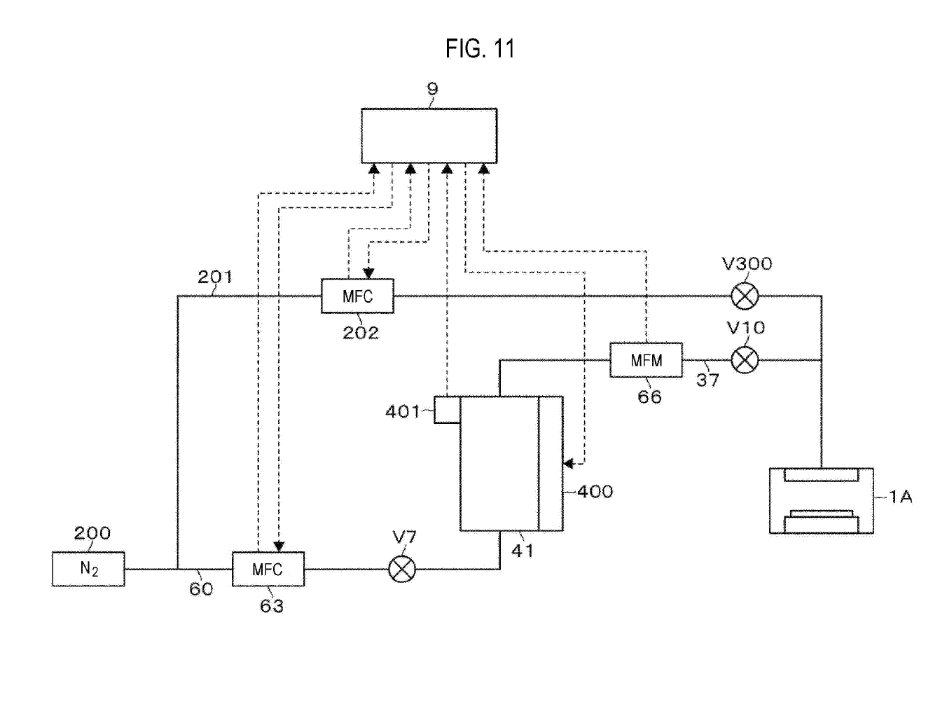

FIG. 11 shows the controller 9 and portions related to the first source material capturing portion 41 for explaining an example in which the first source material capturing portion 41 of the source supply system 2A is used as a source material supplier. In FIG. 11, reference numeral 200 indicates a N₂ gas supplier, reference numeral 400 indicates a temperature adjustment part (the heating part 49 and the coolant passage 53) configured to perform temperature adjustment of the case body 40 of the first source material capturing portion 41, and reference numeral 401 indicates a temperature detector configured to detect temperature of the case body 40. Further, the power supply 84 shown in FIG. 5 is omitted herein. The controller 9 is configured to output a control signal for performing the following operation according to this embodiment based on what is written in the process recipe of the wafer 100 to be treated, the measured flow rate values obtained from each of the mass flow controllers 63, 202 and the mass flow meter 66, and data indicating relationships between temperature, the flow rate of the carrier gas, and the flow rate of the source material. For example, the controller 9 includes a program 91 having a step group for implementing the following operation.

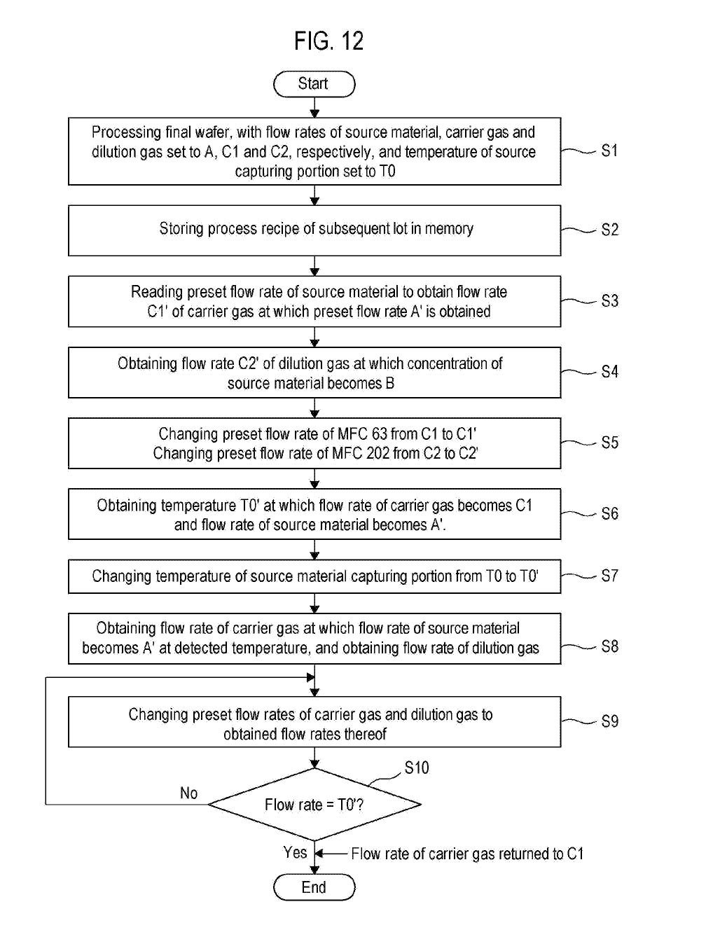

Next, the operation of this embodiment will be described with reference to a flowchart shown in FIG. 12. Now, an assumption that a W layer is formed on a final wafer 100 of one lot transferred into the vacuum container 10 of the film forming processing section 1A by, for example, CVD, using a solid source material WCl₆ and hydrogen gas as described in the above embodiment, and that the wafer 100 is then withdrawn therefrom after completion of film forming thereon, is made. Further, it is assumed that, in the process recipe used for this lot, a preset flow rate of the source material is A. Further, it is assumed that, during the film forming process, a preset temperature of the first source material capturing portion 41 (the case body 40) is T0, a preset flow rate of the carrier gas (a preset flow rate of the mass flow controller 63) is C1, a preset flow rate of the dilution gas (a preset flow rate of the mass flow controller 202) is C2, and the concentration of the source material is B (Step S1).

On the other hand, a carrier receiving a subsequent lot is transferred into a carrier transfer block of a so-called multi-chamber system including the film forming processing section 1A, and a process recipe for the wafers 100 in the subsequent lot is read from the memory 93 of the controller 9 (Step S2). It is assumed that the preset flow rate value of the source material stated in this process recipe is A′, which is greater than A, that is, the preset flow rate value of the source material in the previous lot.

First, before forming a film on a leading wafer 100 in the subsequent lot, the preset flow rate value A′ of the source material is read from the process recipe stored in the memory 93 of the controller 9, and a flow rate C1′ of the carrier gas at which the flow rate of the source material becomes A′ at a temperature T0 of the first source material capturing portion 41 is obtained (Step S3). The flow rate C1′ of the carrier gas is obtained based on correlation data, for example, between the flow rate of the source material and the flow rate of the carrier gas at each temperature previously stored in the memory 93. Alternatively, the flow rate of the source material is adjusted by adjusting the preset flow rate value of the mass flow controller 63 based on the measured flow rate value of each of the mass flow controller 63 and the mass flow meter 66 instead of using the correlation data. Accordingly, the flow rate value of the carrier gas adjusted such that the flow rate of the source material becomes A′ can be set to C1. Further, a flow rate C2′ of the dilution gas at which the concentration of the source material {flow rate of source gas/flow rate of N₂ gas (total flow rate of carrier gas and dilution gas)} becomes B is obtained (Step S4). The flow rate C2′ of the dilution gas is obtained by calculation of (A′/B)-C1′.

Then, the preset flow rate value of the mass flow controller 63 is changed from C1 to C1′ and the preset flow rate value of the mass flow controller 202 is changed from C2 to C2′ (Step S5). Then, a temperature T0′ of the first source material capturing portion 41 at which the flow rate of the source material becomes A′ when the flow rate of the carrier gas is C1 is obtained (Step S6), and a control signal is output to control the temperature adjustment part 400 such that the temperature of the first source material capturing portion 41 becomes T0′ (Step S7). The temperature T0′ of the first source material capturing portion 41 is obtained based on correlation data, for example, between the flow rate of the source material and the temperature of the first source material capturing portion 41 at each flow rate of the carrier gas previously stored in the memory 93.

In Step S3 to Step S7, when increasing the flow rate of the source material from A to A′, first, the flow rate of the carrier gas is instantly increased from C1 to C1′ at which the flow rate of the source material becomes A′ at the temperature T0 (which is a preset temperature in the previous process recipe). As a result, the flow rate of the source material is instantly increased from A to A′. Further, the flow rate of the dilution gas is changed to C2′ such that the concentration of the source material becomes a constant value (in this example, B). On the other hand, the temperature of the first source material capturing portion 41 is increased towards T0′ at which the flow rate of the source material becomes A′ when the flow rate of the carrier gas is an initial flow rate thereof, that is, C1.

Strictly speaking, the timing of changing the preset temperature value of the first source material capturing portion 41 from T0 to T0′ is delayed, as much as the responding times of a series of steps take, when compared with the timing of changing the flow rate of the carrier gas. However, the process time of the step is very short. Thus, the preset temperature of the first source material capturing portion 41 is changed substantially simultaneously with change of the flow rate of the carrier gas. Further, although it is desirable that the timing of changing the preset temperature from T0 to T0′ is performed, as early as possible, immediately after changing the flow rate of the carrier gas in order to secure advantages of the disclosed technology, the timing of changing the preset temperature may be performed after the flow rate of the carrier gas is changed.

As the preset temperature value of the first source material capturing portion 41 is changed to T0′, the temperature of the first source material capturing portion 41 is slowly increased. Then, the controller 9 detects the temperature of the first source material capturing portion 41 during increase in temperature thereof, calculates the flow rate of the carrier gas at which the flow rate of the source material becomes A′ at a detected temperature, and sequentially changes the preset flow rate value of the mass flow controller 63 to the obtained flow rate. At this time, the preset flow rate value of the dilution gas is obtained by securing the flow rate of the dilution gas allowing the concentration of the source material to be a constant value (in this example, B) with respect to each flow rate of the carrier gas, and the preset flow rate value of the mass flow controller 202 are sequentially changed (Step S8, S9).

In this way, in a state where the flow rate of the source material is maintained at A′, the temperature of the first source material capturing portion 41 is slowly increased from T0 while the flow rate of the carrier gas is slowly decreased from C1′ (repetition of Step S9 and Step S10), and, when the temperature reaches T0′, the flow rate of the carrier gas is returned to C1 and a series of processes involved in the change of the flow rate of the source material is completed. Then, film forming process is performed on a wafer 100 in the subsequent lot described above.

According to this method, since the flow rate of the carrier gas is instantly increased, the flow rate of the source material can be instantly changed. Further, while the changed flow rate of the source material is maintained, the flow rate of the carrier gas is returned to, for example, an initial flow rate thereof by adjusting the temperature of the first source material capturing portion 41. Thus, it is possible to adjust the flow rate of the source material in a wide range while maintaining the flow rate of the carrier gas in a desired range.

Further, when the flow rate of the source material is, for example, increased from A to A′, the flow rate C1′ of the carrier gas at which the flow rate A′ of the source material is obtained may be 4 which is a value exceeding an upper limit thereof, due to a large change amount of the flow rate of the source material. In this case, the temperature of the first source material capturing portion 41 is first increased and then the flow rate of the carrier gas is increased. In this case, when the temperature of the first source material capturing portion 41 reaches a temperature at which the flow rate of the source material becomes A′ when the carrier gas flows at an upper limit flow rate thereof, is desirable in that, when the carrier gas flows at the upper limit flow rate, the reduction of operation time is promoted. Further, the temperature of the first source material capturing portion 41 continues to be increased until the flow rate of the source material becomes A′ when the flow rate of the carrier gas is an initial preset flow rate, that is, C1. On the other hand, in response to the increase in temperature of the first source material capturing portion 41, the flow rate of the carrier gas is decreased from the upper limit value of the flow rate to the initial preset flow rate value C1 while the flow rate of the source material is maintained at the flow rate A′.

The changed temperature T0′ may be a temperature at which the flow rate of the source material becomes A′ when the flow rate of the carrier gas is (C1+α) that is greater than C1. In this case, the flow rate of the carrier gas is returned from C1′ to (C1+α) that is greater than the initial flow rate C1.

Furthermore, in the case of decreasing the flow rate of the source material, the carrier gas is first changed, i.e., the flow rate of the carrier gas is increased while decreasing the temperature of the first source material capturing portion 41.

Furthermore, when the process is performed using the second source material capturing portion 42 and the flow rate of the source material is changed, the same operation as described above is performed.

The aforementioned method of changing the flow rate of the source material may also be applied to an ALD process.

It should be understood that the source material used in the film forming process is not limited to WCl₆, and may include, for example, tungsten pentachloride (WCl₅), molybdenum pentachloride (MoCl₅), zirconium (IV) chloride (ZrCl₄), hafnium (IV) chloride (HfCl₄), aluminum trichloride (AlCl₃), and the like.

In the present disclosure, in order to supply a source material sublimated from a solid source material together with a carrier gas to a source consumption zone, a source material supply source is used, in which the source material sublimated from the solid source material is resolidified and precipitated in the form of a thin film. The temperature of the source material supply source is controlled based on the measured value of the flow rate of the source material. In the source material supply source, since the solid source material takes the form of a thin film, the sublimation amount of the solid source material is sensitively changed through temperature adjustment of the source material supply source. Thus, the flow rate of the source material is rapidly increased or decreased promptly when the measured flow rate value of the source material deviates from a preset value. That is, it is possible to make the supply flow rate of the source material stable. Furthermore, it is possible to supply the source material to the source consumption zone with less variation in concentration of the source material than a method of controlling the flow rate of the carrier gas.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A source supply apparatus configured to supply a source material sublimated from a solid source material together with a carrier gas to a source consumption zone, comprising:
a source material supply source defining a sealed space and configured to resolidify and precipitate the source material sublimated from the solid source material in a form of a thin film therein;
a carrier gas supply passage through which the carrier gas is supplied to the source material supply source;
a temperature adjustment part configured to adjust temperature of the source material supply source;
a supply passage through which the source material sublimated from the solid source material and the carrier gas are supplied from the source material supply source to the source consumption zone;
a flow rate measurement part configured to measure a flow rate of the source material supplied from the source material supply source to the source consumption zone; and
a controller configured to control the temperature adjustment part based on a measured flow rate value obtained from the flow rate measurement part.

2. The source supply apparatus according to claim 1, wherein the temperature adjustment part comprises a heating part and a cooling part.

3. The source supply apparatus according to claim 1, wherein the flow rate measurement part comprises:
a flow rate controller provided in the carrier gas supply passage;
a gas flow rate measurement part provided in the supply passage; and
a calculation part configured to calculate the flow rate of the source material based on a measured flow rate value obtained from the gas flow rate measurement part and a preset value of a flow rate of the carrier gas or a measured flow rate value of the carrier gas obtained from the flow rate controller.

4. The source supply apparatus according to claim 1, wherein the source material supply source includes a plurality of source material capturing plates constituting a bent gas flow passage.

5. The source supply apparatus according to claim 4, wherein the source material supply source includes a barrel-shaped container body connected at one end thereof to the carrier gas supply passage and at the other end thereof to the supply passage, and the plurality of source material capturing plates alternately extends from at least one of a left, right, upper and lower inner walls of the barrel-shaped container body so as to constitute the bent gas flow passage bent at a plurality of places.

6. The source supply apparatus according to claim 1, wherein the source material supply source includes a barrel-shaped container body connected at one end thereof to the carrier gas supply passage and at the other end thereof to the supply passage, and the temperature adjustment part includes a heater and a coolant passage installed in walls of the barrel-shaped container body, respectively.

7. The source supply apparatus according to claim 1, further comprising:
a main source container configured to heat the solid source material to a sublimation temperature or more and to receive the solid source material, the carrier gas supply passage being connected to an upstream side of the main source container;
a supplementing passage configured to supply the carrier gas and a source gas containing the source material sublimated from the solid source material from the main source container to the source material supply source;
a discharge passage configured to discharge a gas from the source material supply source while the source gas is supplied from the main source container to the source material supply source;
a valve configured to block the supply passage when the source gas is supplied from the main source container to the source material supply source in order to supplement the source material supply source with the source material; and
a valve configured to block the supplementing passage when the source gas is supplied from the source material supply source to the source consumption zone,
wherein the source material supply source re-solidifies and captures the source material from the source gas supplied from the main source container.

8. A source supply method for supplying a carrier gas together with a source material sublimated from a solid source material to a source consumption zone, comprising:
sublimating the solid source material precipitated in a source material supply source by heating the source material supply source which defines a sealed space and which resolidifies and precipitates the source material sublimated from the solid source material in a form of a thin film therein;
supplying the carrier gas and a sublimated source material from the source material supply source to the source consumption zone though a supply passage by providing the carrier gas into the source material supply source;
measuring a flow rate of the source material supplied from the source material supply source to the source consumption zone; and
controlling a temperature of the source material supply source based on the measured flow rate value of the source material measured in the measuring the flow rate of the source material.

9. The source supply method according to claim 8, wherein, in the measuring the flow rate of the source material, the flow rate of the source material is calculated based on a measured flow rate value of a mixed gas of the source material and the carrier gas flowing through the supply passage disposed at a downstream side of the source material supply source, and a flow rate of the carrier gas flowing through a carrier gas supply passage disposed at an upstream side of the source material supply source.

10. The source supply method according to claim 8, wherein, in order to change a preset value of the flow rate of the source material from a first preset value to a second preset value, the method further comprises:
adjusting a flow rate of the carrier gas to a flow rate at which the flow rate of the source material becomes the second preset value; and
returning the flow rate of the carrier gas, from the adjusted flow rate at which the flow rate of the source material becomes the second preset value to the flow rate available before the adjusting the flow rate of the carrier gas, while the flow rate of the source material is maintained at the second preset value, by adjusting the temperature of the source material supply source.

11. The source supply method according to claim 8, wherein a dilution gas passage connected to the supply passage is used to add a dilution gas to the mixed gas of the carrier gas and the source material sublimated from the source material supply source, and a flow rate of the dilution gas is controlled such that the flow rate of the source material with respect to a total flow rate of the carrier gas and the dilution gas becomes a preset value.

12. A non-transitory computer-readable storage medium storing a computer program used in a source supply apparatus for supplying a carrier gas together with a source material sublimated from a solid source material to a source consumption zone,
wherein the computer program comprises a step group for implementing the source supply method as set forth in claim 8.
